(19) United States
(12) Patent Application Publication
(10) Pub. No.: US 2026/0082902 A1
(43) Pub. Date: Mar. 19, 2026

(54) Bi-Layer In Situ Treated Dielectric Film

(71) Applicant: TEXAS INSTRUMENTS INCORPORATED, Dallas, TX (US)

(72) Inventor: Saiful Islam, Lehi, UT (US)

(21) Appl. No.: 18/927,675

(22) Filed: Oct. 25, 2024

Related U.S. Application Data
(60) Provisional application No. 63/694,226, filed on Sep. 13, 2024.

(51) Int. Cl. H01L 23/532; H01L 21/768

(52) U.S. Cl. CPC H10W 20/48; H10W 20/093; H10W 20/425

(57) ABSTRACT

A semiconductor device is disclosed herein. The semiconductor device includes a first conductive feature disposed over a substrate and a silicon carbon nitride (SiCN) layer disposed over the first conductive feature, wherein the SiCN layer has a nitrogen concentration of greater than about 30% and a carbon concentration of less than about 10%.

### CROSS-REFERENCE TO RELATED APPLICATIONS

This application claims priority to U.S. Provisional Ser. No. 63/694,226, entitled “Bi-layer Insitu Treated SICN dielectric films”, filed Sep. 13, 2024, which is hereby incorporated by reference in its entirety.

### FIELD

The present disclosure generally relates to semiconductor devices, and more particularly, to dielectric films in semiconductor devices.

### BACKGROUND

Integrated circuits may include dielectric films disposed over and/or on conductive features such as metal lines and vias that connect different semiconductor components to each other within an integrated circuit. In some integrated circuits, these dielectric films may form an interface with various conductive features. For example, one such interface may be a dielectric film acting as a barrier layer attempting to isolate an adjacent conductive feature. In other examples, a dielectric film may act as an etch stop layer through which a conductive feature is subsequently formed such that the conductive feature interfaces with the dielectric film. However, problems in an interface between a dielectric film and a conductive feature may affect the electrical and/or structural integrity of the integrated circuit.

### SUMMARY

A semiconductor device is disclosed herein. The semiconductor device includes a first conductive feature disposed over a substrate and a silicon carbon nitride (SiCN) layer disposed over the first conductive feature, wherein the SiCN layer has a nitrogen concentration of greater than about 30% and a carbon concentration of less than about 10%.

Also disclosed herein is a semiconductor device. The semiconductor device includes a conductive feature disposed over a substrate and a silicon carbon nitride (SiCN) layer disposed adjacent the conductive feature, the SiCN layer including a first portion disposed adjacent the conductive feature and a second portion disposed over the first portion, the first portion having a first nitrogen concentration and a first carbon concentration and the second portion having a second nitrogen concentration and a second carbon concentration, the second nitrogen concentration being less than the first nitrogen concentration and the second carbon concentration being greater than the first carbon concentration.

Also disclosed herein is a method. The method includes forming a first silicon carbon nitride (SiCN) layer over a substrate, the first SiCN layer having a first nitrogen concentration and performing a first treatment process on the first SiCN layer to increase nitrogen concentration within the first SiCN layer to form a treated first SiCN layer, the treated first SiCN layer having a second nitrogen concentration that is greater than the first nitrogen concentration.

The foregoing features and elements may be combined in any combination, without exclusivity, unless expressly indicated herein otherwise. These features and elements as well as the operation of the disclosed examples will become more apparent in light of the following description and accompanying drawings.

### BRIEF DESCRIPTION OF THE DRAWINGS

Reference will now be made to the accompanying drawings, which are not necessarily drawn to scale. While the drawings illustrate various examples employing the principles described herein, the drawings do not limit the scope of the claims.

FIG. 1 illustrates a cross-section view of a semiconductor device, in accordance with various examples.

FIG. 2 illustrates a flowchart for a method of forming a semiconductor device, in accordance with various examples.

FIGS. 3A, 3B, 3C, and 3D illustrate cross-section views of a semiconductor device, in accordance with the process of FIG. 2 and the various examples associated therewith.

FIG. 4 illustrates an XPS depth analysis of a semiconductor device, in accordance with various examples.

### DETAILED DESCRIPTION

The following detailed description is presented for purposes of illustration and not of limitation. Benefits, advantages, and/or solutions to problems may be described with reference to various examples. The detailed description makes use of the various examples and refers to the accompanying drawings which illustrate the various examples described herein. The drawings, descriptions, and examples are described in sufficient detail to practice the disclosure. It is understood that connecting lines shown in the various drawings are intended to represent example functional relationships and/or physical couplings between various elements, but that other relationships and/or couplings are possible while remaining within the scope of the present disclosure. It will further be appreciated that the various drawings may not be drawn to scale in order to simplify and clarify the detailed description herein. Furthermore, it is understood that the descriptions and examples contained herein may permit the practice other examples using logical, chemical, and/or mechanical changes without departing from the spirit and scope of this disclosure. For example, the steps recited in method and process descriptions may be executed in a different order, additional process steps may be added, and/or process steps may be removed while remaining within the scope of the present disclosure.

Any reference to singular items and/or examples includes plural items and/or examples and any reference to more than one item and/or example may include a singular item and/or example. Similarly, references to “a”, “an”, or “the” may include one or more of the referenced items, unless stated otherwise. Any reference to connected, coupled, fixed, attached, or the similar words and/or phrases may include partial, full, temporary, removable, permanent, or the other connection options. Any reference to contact, or similar phrase, may include minimal contact or reduced contact. All ranges used herein may include both the upper and lower values of the ranges, including ratio limits, that are disclosed herein. Stated values may include at least the variation that is expected within the field in which the present disclosure is practiced and as would be understood and accepted to include values that are within 10% of a stated value. Similarly, the use of “approximately”, “about”, “substantially” or other similar term represents an amount that is close to the stated value and that may still achieve the stated, or desired, result and/or perform the stated, or desired, function and may refer to an amount that is within 10% of the stated value.

The accompanying drawings, and detailed description of the drawings, include reference numerals that may be repeated across multiple examples. The repetition of reference numerals is intended simplicity and clarity of description and is not intended to form or dictate a relationship between different examples described herein. The examples and descriptions provided herein are intended to be illustrative and not limiting beyond the scope of the claims. The use of terms such as “on” and “over” may indicate that a first feature is formed directly contacting a second feature or may indicate a relationship of the first feature and the second feature without direct contact between the two, such as additional features being formed between the two. For example, “on” may be used to indicate direct contact between the two and “over” may be used to indicate one or more intervening layers between the two.

Spatially relative terms such as, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of discussion herein and are not intended to limit the orientation of the various components, systems, apparatuses, devices, or other features. It is therefore understood and appreciated that the use of the spatially relative terms to practice this disclosure in different orientations remains within the scope of the present disclosure.

The present disclosure relates generally, but not exclusively, to semiconductor processing for forming one or more dielectric material layers (or dielectric films) that help resolve current leakage and improve structural reliability in an integrated circuit device. In that regard, integrated circuits may include dielectric films disposed over and/or on conductive features such as metal lines and vias that connect different semiconductor components to each other within the integrated circuit. One such dielectric material is silicon carbon nitride (SiCN) which is a low-k dielectric material that may be used as barrier layer with respect to a conductive feature and/or an etch stop layer through which a conductive feature is subsequently formed. In examples, where the conductive feature includes a copper-based material, it has been observed that a SiCN layer provides a weak interface (e.g., poor adhesion) with the copper-based material. This weak interface may cause the SiCN layer to delaminate from the copper-based material and allow the copper-based material to migrate, which may cause reliability issues. For example, because copper atoms are quite mobile, a weak interface between a SiCN layer and a copper-based material, and the subsequent copper migration, may cause current leakage, via stress migration (VSM), via chain shorts (VCS), and/or stress induced voiding (SIV) in an integrated device.

To address these issues, disclosed herein are methods of forming a nitrogen-rich in situ treated silicon carbon nitride (SiCN) layer that forms a strong interface with copper-based material of a conductive feature. In some examples, the disclosed methods form a multilayered SiCN film having two layers, also referred to as a bi-layer SiCN film. The bi-layer SiCN film includes a nitrogen-rich SiCN layer and a carbon-rich SiCN layer that is formed over the nitrogen-rich SiCN layer. In some examples, the nitrogen-rich SiCN layer has a nitrogen concentration (e.g., an average concentration) greater than about 30% and a carbon concentration (e.g., an average concentration) less than about 10%. The bi-layer SiCN film, and more specifically the nitrogen-rich SiCN layer, improves the adhesion of the bi-layer SiCN film to the conductive feature (e.g., the copper-based material). Devices formed using the methods of forming the bi-layer SiCN film are generally more robust and have fewer stress related defects. That is, these devices avoid and/or prevent stress related defects such as via stress migration (VSM), via chain shorts (VCS), and stress induced voiding (SIV) that may otherwise be associated with a weaker interface between SiCN and a conductive feature.

The methods disclosed herein describe forming a multilayered SiCN film over a conductive feature. Prior to forming the multilayered SiCN film, a thermal process (e.g., a pre-bake process) is performed to remove volatile materials from a workpiece that includes the conductive feature. Thereafter, a first layer of the multilayered SiCN film is formed using trimethyl silane (TMS), ammonia (NH₃), nitrogen (N₂), and argon (Ar) in a first deposition process, which may also be referred to as a slow deposition process in view of a relatively low deposition rate (e.g., when compared to the second deposition process described below). The first deposition process forms a SiCN layer that is subsequently treated as described herein. After the first deposition process, an in situ treatment process is performed on the SiCN layer. The in situ treatment process may further densify the SiCN layer, further increase nitrogen (N₂) concentration, and further reduce carbon (C) concentration resulting in an in situ treated nitrogen-rich silicon carbon nitride (IT-SiCN) layer. The increased density and nitrogen concentration of the IT-SiCN layer promotes better adhesion to the conductive feature. Moreover, the IT-SiCN layer may provide better step coverage over an underlying conductive feature. The IT-SiCN layer may be referred to as a nitrogen-rich SiCN layer (N-rich SiCN layer) hereinafter.

A second layer of the multilayered SiCN film is then formed over and/or on the IT-SiCN layer based on a second deposition process, which may also be referred to as a fast deposition process in view of a relatively high deposition rate (e.g., when compared to the first deposition process). The second deposition process uses trimethyl silane (TMS), ammonia (NH₃), and nitrogen (N₂). Unlike the slow deposition process, the fast deposition process is performed in the absence of applying Ar gas. The second layer formed based on the fast deposition is a carbon-rich SiCN layer. As a result of the slow deposition process and the in situ treatment process, the IT-SiCN layer is denser and has a higher nitrogen concentration and lower carbon concentration than the carbon-rich SiCN layer. Using multiple deposition processes (e.g., slow and fast deposition processes) improves the adhesion of the multilayered SiCN film to the conductive feature without significantly increasing the processing time.

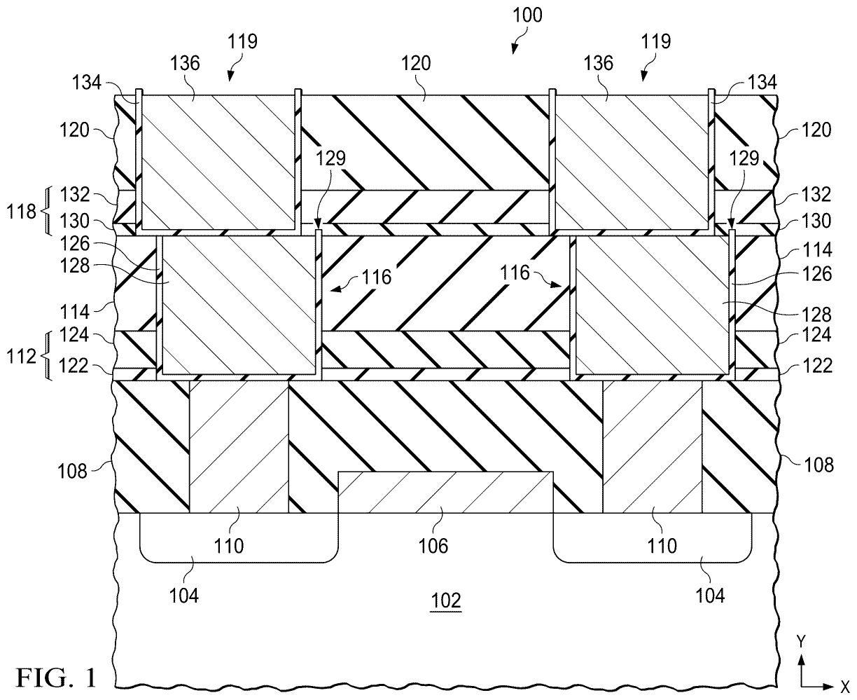

Referring now to FIG. 1, a diagrammatic cross-sectional view of a device 100 is illustrated according to various aspects of the present disclosure. In various examples, device 100 is or may be a part of a larger semiconductor device including multiple levels, metal lines, conductive interconnections, field effect transistors (FETs), dielectric materials, and/or other materials and/or structures. Additional features can be added to device 100, and some features described below can be replaced, modified, or eliminated in other examples of device 100.

As described below, device 100 incorporates a nitrogen-rich silicon carbon nitride (SiCN) layer (IT-SiCN layer) providing improved adhesion to the conductive features (e.g., copper-based materials). In some examples, the nitrogen-rich SiCN layer has a nitrogen concentration greater than about 30% and a carbon concentration less than about 10%. The improved adhesion of the nitrogen-rich SiCN layer to the conductive feature (e.g., the copper-based material) avoids and/or prevents current leakage and stress related defects that may otherwise be associated with a weaker interface between SiCN and a conductive feature. Some examples of stress related defects that may avoided by using the disclosed nitrogen-rich SiCN layer include via stress migration (VSM), via chain shorts (VCS), and stress induced voiding (SIV).

Device 100 includes a substrate 102, source/drain regions 104, a gate stack 106, a first dielectric layer 108, source/drain contacts 110, a first multilayered silicon carbon nitride (SiCN) film 112, a second dielectric layer 114, first conductive features 116, a second multilayered SiCN film 118, second conductive features 119, and a third dielectric layer 120.

Substrate 102 may include a bulk semiconductor substrate, a semiconductor-on-insulator (SOI) substrate, or any other appropriate substrate. For example, the substrate 102 may be or include a bulk silicon wafer. In various examples, substrate 102 may include a dielectric material, an epitaxially grown material, and/or any other any material and/or layer on which the process described herein may be performed.

Source/drain regions 104 may be formed in or on substrate 102. In various examples, one or more materials may be formed, deposited, or grown on substrate 102 to form source/drain regions 104. For example, an etching process may be performed on substrate 102 to form recesses in which an epitaxial growth process is then performed to grow a semiconductor material to form source/drain regions 104. In other examples, substrate 102 is doped to form source/drain regions 104. In various examples, each of source/drain regions 104 may undergo a doping process, such as for example, one or more ion implantation processes. Source/drain regions 104 may be doped with p-type dopants or n-type dopants depending on the desired design requirements. Additionally, source/drain regions 104 may include silicide features formed of silicon and at least one of cobalt, nickel, or titanium (e.g., CoSi₂, Ni₂Si and/or TiSi₂). These silicide features reduce resistance of the subsequently formed contact (e.g., source/drain contacts 110) thereover.

Gate stack 106 is formed over substrate 102 and between source/drain regions 104. Gate stack 106 (e.g., gate structure) may include a gate dielectric layer and a gate electrode layer. The gate dielectric layer may include any gate dielectric material including a high-k dielectric material (e.g., dielectric constant greater than silicon oxide). In various examples, the dielectric layer may include materials such as silicon oxide, hafnium oxide, and/or zirconium oxide. The use of the term silicon oxide throughout this disclosure includes materials such as silicon monoxide (SiO) and/or silicon dioxide (SiO₂) and/or a non-stoichiometric mixture of the two. The gate electrode layer may include any gate electrode material layer(s). In various examples the gate electrode layer may include, polycrystalline silicon, also referred to as polysilicon. In other examples, the gate electrode layer may include other metals and metal alloys. For example, the gate electrode layer may include metal alloys such as titanium nitride (TiN) and/or tantalum nitride (TaN). In other examples, the gate electrode layer may include copper (Cu), tungsten (W), and/or aluminum (Al).

First dielectric layer 108 (or first interlayer dielectric layer) is formed over substrate 102, source/drain regions 104, and gate stack 106. In various examples, first dielectric layer 108 may be a single dielectric layer or may include multiple dielectric layers of a same dielectric material or different dielectric materials. In various examples, first dielectric layer 108 layer may include silicon oxide, silicon nitride, silicon oxynitride, a silicon oxide-based material (such as a phosphosilicate glass (PSG) or a tetraethyl orthosilicate (TEOS) oxide), polytetrafluoroethylene, low-k dielectric material layers, any other dielectric material, or any combination thereof.

Source/drain contacts 110 extend through first dielectric layer 108 to connect to source/drain regions 104. In some examples, source/drain contacts 110 electrically connect source/drain regions 104 to one or more first conductive features 116. In various examples, trenches are formed through first dielectric layer 108 to expose source/drain regions 104.

Source/drain contacts 110 are then formed in such trenches over source/drain regions 104. In some examples, source/drain contacts 110 interface with silicide features of the source/drain regions 104. In various examples, the trenches may be formed through first dielectric layer 108 using one or more etching processes. Source/drain contacts 110 may each include (i) one or more metal-barrier and/or adhesion layers (e.g., titanium nitride (TiN), tantalum nitride (TaN), the like, or a combination thereof) conformally in a respective trench through first dielectric layer 108 and (ii) a fill metal (e.g., aluminum (Al), tungsten (W), the like, or a combination thereof) over and/or on the metal-barrier and/or adhesion layer(s).

First multilayered SiCN film 112 (or first bi-layer SiCN film) is formed over first dielectric layer 108 and source/drain contacts 110. First multilayered SiCN film 112 includes a first nitrogen-rich silicon carbon nitride (N-rich SiCN) layer 122 and a first carbon-rich silicon carbon nitride (C-rich SiCN) layer 124. The term “nitrogen-rich” refers to first N-rich SiCN layer 122 having a greater concentration of nitrogen when compared to the first C-rich SiCN layer 124. Moreover, the first N-rich SiCN layer 122 includes a greater concentration of nitrogen than carbon therein. Similarly, the term “carbon-rich” refers to first C-rich SiCN layer 124 having a greater concentration of carbon when compared to the first N-rich SiCN layer 122. First multilayered SiCN film 112 may be formed using one or more processes. For example, first N-rich SiCN layer 122 may be formed over first dielectric layer 108 and source/drain contacts 110 using one or more processes and first C-rich SiCN layer 124 may be formed over first N-rich SiCN layer 122 using one or more different processes. In some examples, first N-rich SiCN layer 122 and first C-rich SiCN layer 124 have different physical properties such as different nitrogen concentration, carbon concentration, refractive index, dielectric constant, density, and breakdown voltage, among others.

First N-rich SiCN layer 122, in various examples, has a nitrogen concentration of greater than about 30%. In various examples, first N-rich SiCN layer 122 has a nitrogen concentration of about 40% to about 50%. In various examples, first N-rich SiCN layer 122 has a carbon concentration of less than about 10%. In various examples, first N-rich SiCN layer 122 has a carbon concentration of about 5% to about 15%. In various examples, first N-rich SiCN layer 122 has a refractive index of about 1.88 to about 1.90, and more specifically, about 1.89. In various examples, first N-rich SiCN layer 122 has a dielectric constant of about 5.8 to about 6.2, and more specifically, about 5.9 to about 6.1. In various examples, first N-rich SiCN layer 122 has a density of about 2.4 g/cm³ to about 2.8 g/cm³, and more specifically, about 2.6 g/cm³ to about 2.7 g/cm³. In various examples, first N-rich SiCN layer 122 has a breakdown voltage of about 7 MV/cm to about 7.6 MV/cm, and more specifically, about 7.2 MV/cm to about 7.4 MV/cm.

First C-rich SiCN layer 124, in various examples, has a nitrogen concentration of less than about 30%. In various examples, first C-rich SiCN layer 124 has a nitrogen concentration of about 20% to about 30%. In various examples, first C-rich SiCN layer 124 has a carbon concentration of greater than about 20%. In various examples, first C-rich SiCN layer 124 has a carbon concentration of about 25% to about 35%. In various examples, first C-rich SiCN layer 124 has a refractive index of about 1.86 to about 1.88, and more specifically, about 1.87. In various examples, first C-rich SiCN layer 124 has a dielectric constant of about 5.0 to about 5.3, and more specifically, about 5.1 to about 5.2. In various examples, first C-rich SiCN layer 124 has a density of about 1.9 g/cm³ to about 2.3 g/cm³, and more specifically, about 2.0 g/cm³ to about 2.2 g/cm³. In various examples, first C-rich SiCN layer 124 has a breakdown voltage of about 5.3 MV/cm to about 5.9 MV/cm, and more specifically, about 5.5 MV/cm to about 5.7 MV/cm.

Accordingly, in some examples, first N-rich SiCN layer 122 has higher concentration of nitrogen and a lower concentration of carbon than first C-rich SiCN layer 124. Moreover, in some examples, the relative concentrations of nitrogen and carbon in each layer of first multilayered SiCN film 112 (e.g., first N-rich SiCN layer 122 and first C-rich SiCN layer 124) are substantially uniform throughout the thickness of each layer. That is, the concentrations of nitrogen and carbon in first N-rich SiCN layer 122 are substantially uniform throughout first N-rich SiCN layer 122 and the concentrations of nitrogen and carbon are substantially uniform throughout first C-rich SiCN layer 124. In some examples, substantially uniform concentration means that there is no more than a +/−10% variance in concentration within the layer. The difference in the concentration of nitrogen and carbon may be viewed using various physical tests, such as for example, x-ray photoelectron spectroscopy (XPS), ultraviolet photoelectron spectroscopy (UPS), or transmission electron microscopy (TEM), among others. For example, an analysis of first multilayered SiCN film 112 of device 100 using an XPS shows a change in nitrogen concentration and carbon concentration at the interface of first N-rich SiCN layer 122 and first C-rich SiCN layer 124. Specifically, in some examples, such analyses show an increase in nitrogen concentration and decrease in carbon concentration across the interface from first C-rich SiCN layer 124 to first N-rich SiCN layer 122.

With respect to device 100, as described below, first multilayered SiCN film 112 is formed over first dielectric layer 108 and source/drain contacts 110 prior to the formation of first conductive features 116 through first multilayered SiCN film 112. That is, first multilayered SiCN film 112 is formed on source/drain contacts 110 prior to the formation of first conductive features 116 and acts like an etch stop layer during the formation of first conductive features 116. In various examples, first N-rich SiCN layer 122 may be formed by a chemical vapor deposition (CVD) process, a plasma enhanced chemical vapor deposition (PECVD) process, other suitable processing techniques, or a combination thereof.

Second dielectric layer 114 is formed over first multilayered SiCN film 112. As illustrated in FIG. 1, second dielectric layer 114 is formed over first C-rich SiCN layer 124. Second dielectric layer 114 may be formed similar to first dielectric layer 108. In various examples, second dielectric layer 114 may include similar materials as first dielectric layer 108. In various examples, second dielectric layer 114 may include different materials than first dielectric layer 108.

First conductive features 116 extend from source/drain contacts 110, through first multilayered SiCN film 112, including first N-rich SiCN layer 122 and first C-rich SiCN layer 124, and second dielectric layer 114 to second multilayered SiCN film 118. As described above, first multilayered SiCN film 112 acts as an etch stop layer during the formation of first conductive features 116. In that regard, a first etching process may be used to form openings through second dielectric layer 114 that stops on first multilayered SiCN film 112. Then a second etching process may be performed to etch through first multilayered SiCN film 112, including through first C-rich SiCN layer 124 and first N-rich SiCN layer 122, to expose source/drain contacts 110. First conductive features 116 are then formed in such openings over the exposed source/drain contacts 110.

Each first conductive feature 116 includes a first liner layer 126 and a first conductive material layer 128. First liner layer 126 is formed in the openings and over source/drain contacts 110 and sidewalls of first multilayered SiCN film 112 and second dielectric layer 114. In various examples, first liner layer 126 may include titanium (Ti), titanium nitride (TiN), tantalum (Ta), tantalum nitride (TaN), the like, or a combination thereof. In various examples, first liner layer 126 may be formed by a physical vapor deposition (PVD), a chemical vapor deposition (CVD) process, other suitable processing techniques, or a combination thereof.

First conductive material layer 128 is formed over first liner layer 126 including in the openings through second dielectric layer 114 and first multilayered SiCN film 112. In various examples, first conductive material layer 128 may be or include a fill metal such as aluminum (Al), copper (Cu), tungsten (W), the like, or a combination thereof. In various examples, first conductive material layer 128 may be formed by a physical vapor deposition (PVD), a chemical vapor deposition (CVD) process, electroplating process, a sputtering process, other suitable processing techniques, or a combination thereof.

Accordingly, as shown in FIG. 1, first liner layer 126 is disposed along a bottom surface and sidewalls of first conductive material layer 128 in each conductive feature 116. In various examples, the processes used to form first conductive features 116 may cause protrusions 129 (e.g., portions) of first liner layer 126 to extend above a top surface of first conductive material layer 128 in a first direction (e.g., the positive y-direction). For example, a chemical mechanical polishing (CMP) process may be used after forming first liner layer 126 and first conductive material layer 128 to remove excess materials on top of second dielectric layer 114 resulting in a top surface of the first conductive features 116 being planarized. However, such a CMP process may remove first conductive material layer 128 at a higher rate than first liner layer 126, leaving one or more protrusions 129 extending above first conductive material layer 128. As illustrated in FIG. 1, protrusions 129 of first liner layer 126 (e.g., fangs or portions) may be exaggerated for discussion purposes.

Second multilayered SiCN film 118 (or second bi-layer SiCN film) is formed over second dielectric layer 114 and first conductive features 116, including over first liner layer 126 and first conductive material layer 128. Second multilayered SiCN film 118 includes a second N-rich SiCN layer 130 and a second C-rich SiCN layer 132. Second N-rich SiCN layer 130 and second C-rich SiCN layer 132 may be formed in similar processes to those described above with respect to first N-rich SiCN layer 122 and first C-rich SiCN layer 124. Accordingly, second N-rich SiCN layer 130 and second C-rich SiCN layer 132 may have similar physical properties as described above with respect to first N-rich SiCN layer 122 and first C-rich SiCN layer 124, respectively.

Similar to first N-rich SiCN layer 122, second N-rich SiCN layer 130 allows for improved adhesion to the first conductive features 116 (e.g., copper-based materials). In examples, where first conductive features 116 include a copper-based material the nitrogen-rich properties of second N-rich SiCN layer 130 allows for improved adhesion to first conductive features 116. In some examples, second N-rich SiCN layer 130 has a nitrogen concentration greater than about 30% and a carbon concentration less than about 10%. Because a nitrogen-rich SiCN layer improves adhesion to the conductive feature (e.g., the copper-based material) this in turn avoids and/or prevents current leakage and stress related defects such as via stress migration (VSM), via chain shorts (VCS), and stress induced voiding (SIV) that may otherwise be associated with a weaker interface between SiCN and a conductive feature.

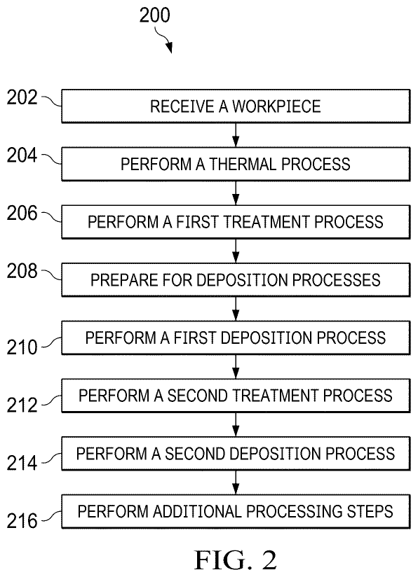

Moreover, as described below (see FIG. 2 and method 200), the process of forming second N-rich SiCN layer 130 uses a lower RF power which reduces adverse sputtering effects on the copper-based materials of the first conductive features 116. This results in preventing or reducing a dishing effect on the first conductive features 116 that may otherwise occur during the formation of a SiCN layer over the conductive features using a higher RF power. Additionally, inadvertent copper contamination from sputtered copper in device 100 is reduced and/or prevented because of the lower RF power used during the formation of second N-rich SiCN layer 130.

Additionally, as described below with respect to method 200 of FIG. 2, during the formation processes, N-rich SiCN layers 122, 130 may be formed based on a relatively slow deposition process which improves conformality to the underlying surfaces. For example, as shown in FIG. 1, because of this slow deposition process second N-rich SiCN layer 130 conforms to the top surfaces of second dielectric layer 114, first liner layer 126, and first conductive material layer 128 and to the side surfaces of protrusion 129. That is, as illustrated in FIG. 1, second N-rich SiCN layer 130 fills in spaces between the top surface of first conductive material layer 128 and the sidewall of protrusion 129 of first liner layer 126 so that no voids are formed at the intersection of first conductive material layer 128 and protrusion 129.

Third dielectric layer 120 is formed over second multilayered SiCN film 118. As illustrated in FIG. 1, third dielectric layer 120 is formed over second C-rich SiCN layer 132. Third dielectric layer 120 may be formed using similar processes as those described above with respect to first dielectric layer 108 and second dielectric layer 114. Third dielectric layer 120 may be or include similar materials as those described above with respect to first dielectric layer 108 and second dielectric layer 114.

As described above with respect to the formation of first conductive features 116, a first etching process may be used to form openings through third dielectric layer 120 that stops on second multilayered SiCN film 118. That is, second multilayered SiCN film 118 acts like an etch stop layer during the formation of second conductive features 119. Then a second etching process may be performed to etch through second multilayered SiCN film 118, including through second N-rich SiCN layer 130 and second C-rich SiCN layer 132, to expose first conductive features 116. Second conductive features 119 are then formed in such openings over the exposed first conductive features 116.

Each second conductive feature 119 includes a second liner layer 134 and a second conductive material layer 136. Second liner layer 134 is formed in openings through third dielectric layer 120 and second multilayered SiCN film 118. Second liner layer 134, in various examples, may include similar materials and be formed using similar processes as those described above with respect to first liner layer 126. Second conductive material layer 136 is formed over second liner layer 134 including in the openings through third dielectric layer 120 and second multilayered SiCN film 118. Second conductive material layer 136, in various examples, may include similar materials and be formed using similar processes as those described above with respect to first conductive material layer 128.

Accordingly, device 100 incorporates a multilayered SiCN layer having N-rich SiCN layers (e.g., first N-rich SiCN layer 122 and second N-rich SiCN layer 130). These N-rich SiCN layers allows for improved adhesion to the conductive features (e.g., copper-based materials). In some examples, N-rich SiCN layers 122, 130 have a nitrogen concentration greater than about 30% and a carbon concentration less than about 10%. Because N-rich SiCN layers 122, 130 improve adhesion to source/drain contacts 110, first conductive features 116 and/or second conductive features 119 (e.g., the copper-based material) this in turn avoids and/or prevents current leakage and stress related defects such as via stress migration (VSM), via chain shorts (VCS), and stress induced voiding (SIV) that may otherwise be associated with a weaker interface between SiCN and a conductive feature.

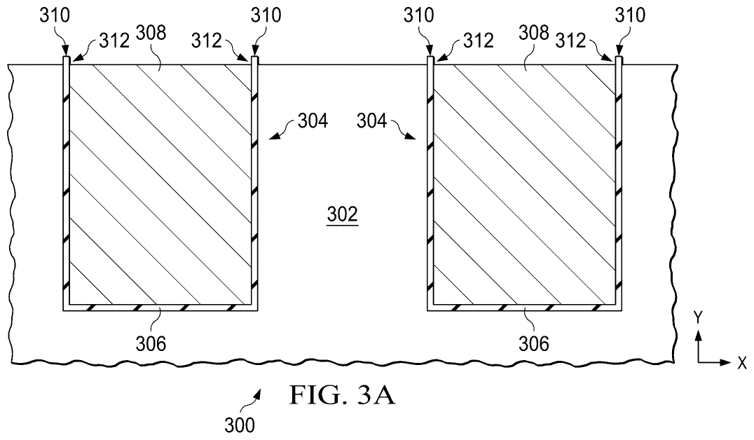

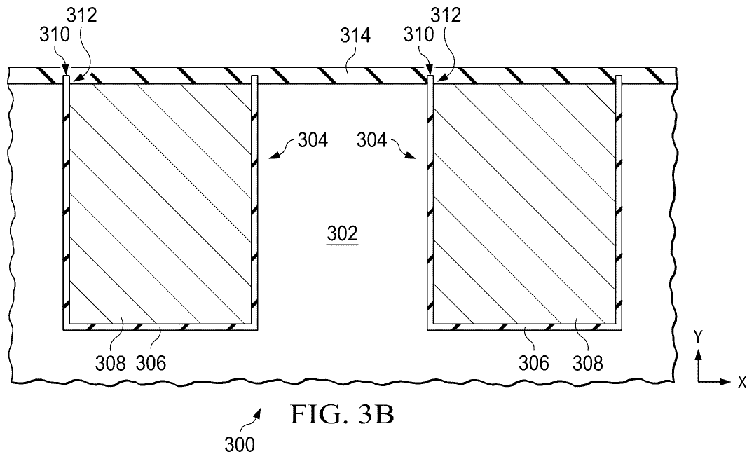

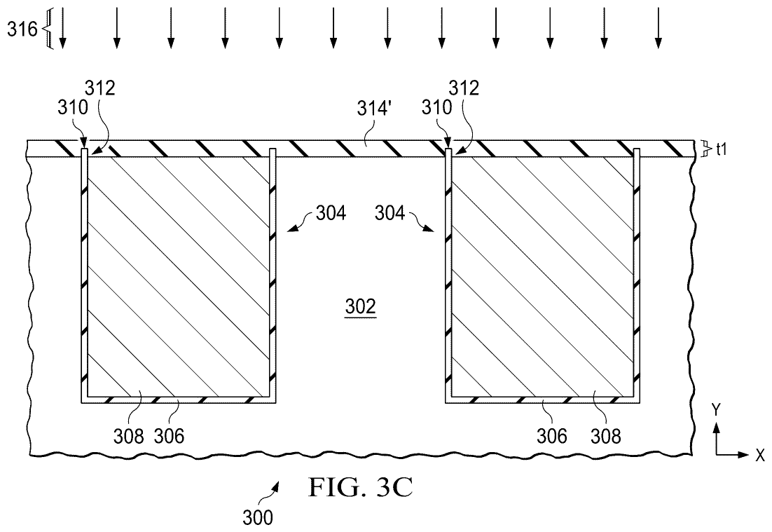

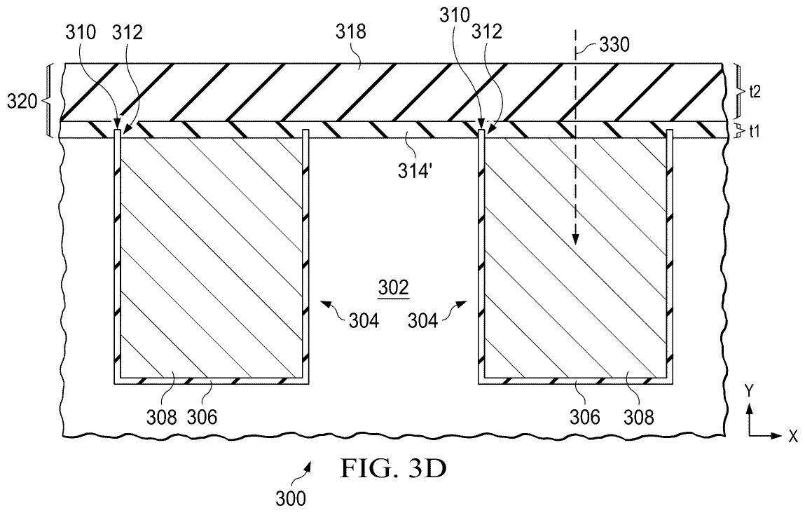

Referring now to FIG. 2, a flow diagram of a method 200 for forming a multilayered silicon carbon nitride (SiCN) film in a semiconductor device is illustrated, in accordance with various examples of the present disclosure. In various examples, method 200 may be used to form a multilayered SiCN film (e.g., multilayered SiCN film 112, multilayered SiCN film 118) over and/or on various material layers including other dielectric material layers and conductive material layers associated with integrated circuit components. Additional processes can be provided before, during, and after method 200. In various examples, method 200 may be used to form a portion of device 100, described above in FIG. 1. As discussed below, method 200 is described with reference to FIGS. 3A-3D.

As described above, the present disclosure relates generally, but not exclusively, to semiconductor processing for forming one or more dielectric material layers (or dielectric films) that help resolve current leakage and improve structural reliability in an integrated circuit device. In that regard, integrated circuits may include dielectric films disposed over and/or on conductive features such as metal lines and vias that connect different semiconductor components to each other within the integrated circuit. One such dielectric material is silicon carbon nitride (SiCN) which is a low-k dielectric material that may be used as a barrier layer with respect to a conductive feature and/or an etch stop layer through which a conductive feature is subsequently formed. In examples where the conductive feature includes a copper-based material, it has been observed that a SiCN layer provides a weak interface (e.g., poor adhesion) with the copper-based material. This weak interface may cause the SiCN layer to delaminate from the copper-based material which may cause reliability issues. For example, because copper atoms are quite mobile, a weak interface between a SiCN layer and a copper-based material may cause current leakage, via stress migration (VSM), via chain shorts (VCS), and/or stress induced voiding (SIV) in an integrated device.

To address these issues, method 200 forms a nitrogen-rich in situ treated silicon carbon nitride (SiCN) layer (IT-SiCN layer) that enables a strong interface (e.g., improved adhesion) with copper-based material of a conductive feature. In some examples, the nitrogen-rich SiCN layer has a nitrogen concentration greater than about 30% and a carbon concentration less than about 10%. Because a nitrogen-rich SiCN layer improves adhesion to the conductive feature (e.g., the copper-based material) this in turn avoids and/or prevents current leakage and stress related defects such as via stress migration (VSM), via chain shorts (VCS), and stress induced voiding (SIV) that may otherwise be associated with a weaker interface between SiCN and a conductive feature.

In that regard, FIGS. 3A-3D are diagrammatic cross-sectional views of a device 300 at various stages of fabrication (such as those associated with method 200 of FIG. 2) according to various aspects of the present disclosure. In various examples, device 300 may be an integrated circuit device that includes various transistors such as a field effect transistor (FET). Additional features can be added to device 300, and some features described below can be replaced, modified, or eliminated in other examples of device 300. In various examples, device 300 may be a portion of device 100 described above in FIG. 1. In various examples, device 300 may have undergone a damascene process before beginning the steps of method 200. That is, a conductive feature may be formed on device 300 based on a damascene process prior to performing method 200. For example, a hard mask may be formed over a dielectric layer and then be used to etch a trench in the dielectric layer. A conductive feature (e.g., copper) may be formed over the dielectric layer and in the trench using one or more processing steps, such as depositing a seed layer, electroplating the seed layer, etc. A planarization process is then performed to remove excess conductive materials from device 300.

At step 202, a workpiece is received. As shown in FIG. 3A, device 300 (e.g., a workpiece) includes a dielectric layer 302 and conductive features 304 at least partially disposed in the dielectric layer 302. In various examples, dielectric layer 302 may include one or more dielectric materials formed over a semiconductor substrate such that conductive features 304 are at least partially disposed in the one or more dielectric material layers - e.g., first dielectric layer 108, a combination of first multilayered SiCN film 112 and second dielectric layer 114, a combination of second multilayered SiCN film 118 and third dielectric layer 120. In various examples, dielectric layer 302 may be a single dielectric layer or may include multiple dielectric layers of a same dielectric material or different dielectric materials. In various examples, the one or more dielectric material layers of dielectric layer 302 may include silicon oxide, silicon nitride, silicon oxynitride, a silicon oxide-based material (such as a phosphosilicate glass (PSG) or a tetraethyl orthosilicate (TEOS) oxide), polytetrafluoroethylene, low-k dielectric material layers, any other dielectric material, or any combination thereof. In some examples, dielectric layer 302 may be an example of one of first dielectric layer 108, second dielectric layer 114, and/or third dielectric layer 120, or a combination thereof described above with respect to FIG. 1.

As shown in FIG. 3A, in various examples, conductive features 304 may extend into dielectric layer 302 without extending through dielectric layer 302. That is, a portion of dielectric layer 302 may be disposed below (or underneath) conductive features 304 such that conductive features 304 do not extend completely through dielectric layer 302. In other examples, conductive features 304 may extend through dielectric layer 302 to connect to other conductive features such as how conductive feature 116 extends through second dielectric layer 114 to connect to source/drain contact 110 described above with respect to FIG. 1. As such, in some examples, conductive features 304 may be an example of first conductive features 116 described above with respect to device 100 in FIG. 1.

Conductive features 304 each include a liner layer 306 and a conductive material layer 308. Conductive features 304 further include one or more protrusions 310 (e.g., fangs or portions) created by liner layer 306 extending above (e.g., in the positive Y-direction) a top surface of dielectric layer 302 and a top surface of conductive material layer 308. Protrusions 310 may be caused by processing steps prior to FIG. 3A, such as for example, a chemical mechanical polishing (CMP) process the removes material from dielectric layer 302 and conductive material layer 308 at a higher rate than liner layer 306, leaving one or more protrusions 310 above both dielectric layer 302 and conductive material layer 308. The resulting protrusions 310 creates a corner 312 at the intersection of conductive material layer 308 and protrusions 310. In various examples, liner layer 306, conductive material layer 308, and one or more protrusions 310 may be examples of first liner layer 126, first conductive material layer 128, and protrusions 129, respectively, as described above with respect to device 100 in FIG. 1.

At step 204, a thermal process (e.g., a pre-bake process) is performed to remove volatile materials from the workpiece. With continuing reference to FIG. 3A, in various examples, a thermal process is performed on dielectric layer 302 including conductive features 304 formed therein. The thermal process removes volatile materials, including moisture (e.g., H₂O), from dielectric layer 302 and conductive features 304. In various examples, volatile materials may have been introduced to dielectric layer 302 and/or conductive feature 304 during processing steps used to form dielectric layer 302 and/or conductive features 304. For example, dielectric materials of dielectric layer 302 may be quite porous and absorb contaminants materials (e.g., volatile materials) associated with previous etching process, environmental moisture/gases, and/or CMP processes. Removing the volatile materials (e.g., degassing) from dielectric layer 302 and conductive feature 304 also improves oxide removal in later steps and increases adhesion of the later formed N-rich SiCN layer to conductive feature 304, as will be described in more detail below.

The thermal process may be performed using one or more gases at a set temperature and a set pressure for a set period of time. In various examples, the one or more gases may include nitrogen (N₂), helium (He), other suitable gases, or a combination thereof. In various examples, the thermal process may be performed at a temperature of about 300° C. to about 400° C., and more specifically, about 325° C. to about 375° C. In various examples, the thermal process may be performed at a pressure of about 2 Torr to about 5 Torr, and more specifically, about 3 Torr to about 4 Torr. In various examples, the thermal process may be performed for about 20 seconds to about 60 seconds, and more specifically, about 30 seconds to about 50 seconds.

At step 206, a first treatment process is performed to remove oxide from device 300 including surfaces of the conductive feature 304, and more specifically, conductive material layer 308. With continuing reference to FIG. 3A, and as described above, conductive material layer 308 may be or include a fill metal such as aluminum (Al), copper (Cu), tungsten (W), the like, or a combination thereof. After forming conductive material layer 308 and during subsequent processing steps, an oxide layer may form on the surface of conductive material layer 308. For example, when conductive material layer 308 includes copper (Cu), a copper oxide (CuO) may form on conductive material layer 308. Performing the first treatment process removes the oxide which improves the adhesion between conductive material layer 308 and subsequent layers formed over conductive material layer 308 (e.g., a N-rich SiCN layer).

The first treatment process may be performed using one or more gases at a set temperature and a set pressure for a set period of time. In various examples, the one or more gases may include ammonia (NH₃), nitrogen (N₂), other suitable gases, or a combination thereof, each of which has a set flowrate. In various examples, the set flow rate of NH₃ may be about 80 sccm to about 300 sccm, and more specifically, about 120 sccm to about 200 sccm. In various examples, the set flow rate of N₂ may be about 10,000 sccm to about 25,000 sccm, and more specifically, about 16,000 sccm to about 20,000 sccm. In various examples, the first treatment process may be performed at a temperature of about 300° C. to about 400° C., and more specifically, about 325° C. to about 375° C. In various examples, the first treatment process may be performed at a pressure of about 2 Torr to about 5 Torr, and more specifically, about 3 Torr to about 4 Torr. In various examples, the first treatment process may be performed for about 5 seconds to about 45 seconds, and more specifically, about 15 seconds to about 30 seconds.

At step 208, device 300 is prepared for deposition processes to form a multilayered SiCN film similar to first multilayered SiCN film 112 or second multilayered SiCN film 118 discussed above with respect to FIG. 1. Various parameters of subsequent processing steps may be initialized to prepare device 300 for the deposition processes including gas flows, temperature, pressure, etc. Accordingly, the process of step 208 may vary based on the parameters of subsequent steps.

At step 210, a first deposition process is performed. As shown in FIG. 3B, a SiCN layer 314 is formed over dielectric layer 302 and conductive feature 304, including over liner layer 306 and conductive material layer 308. The first deposition process may be referred to as a slow deposition process that has a deposition rate of about 5 Å/sec or less. In other examples, the slow deposition rate may be about 2.5 Å/sec to about 7.5 Å/sec. The slow deposition rate may facilitate SiCN layer 314 to conform along the surfaces of conductive feature 304 including the top surface of conductive material layer 308 and the top and side surfaces of liner layer 306. Specifically, the conformality of SiCN layer 314 fills corner 312 at the intersection of conductive material layer 308 and one or more protrusions 310 of liner layer 306. In other words, there are no gaps, or voids, between SiCN layer 314 and liner layer 306 or conductive material layer 308. Additionally, the slow rate of deposition, in combination with the processing parameters described below, may increase nitrogen (N₂) concentration in SiCN layer 314 during the first deposition process.

The first deposition process may be performed using one or more gases, at a first radio frequency (RF) power, at a first pressure, and at a first temperature. In various examples, the one or more gases may include trimethyl silane (TMS), ammonia (NH₃), nitrogen (N₂), and argon (Ar), each having a first flow rate. In various examples, the first flow rate of TMS may be about 85 sccm to about 105 sccm, and more specifically, about 90 sccm to about 100 sccm. In various examples, the first flow rate of NH₃ may be about 1,000 sccm to about 1,200 sccm, and more specifically, about 1,050 sccm to about 1,150 sccm. In various examples, the first flow rate of N₂ may be about 1,350 sccm to about 1,650 sccm, and more specifically, about 1,450 sccm to about 1,550 sccm. In various examples, the first flow rate of Ar may be about 2,800 sccm to about 3,400 sccm, and more specifically, about 3,000 to about 3,200 sccm. In various examples, the first RF power may be about 210 W to about 265 W, and more specifically, about 220 W to about 255 W. In various examples, the first pressure may be about 2.9 Torr to about 3.5 Torr, and more specifically, about 3.0 Torr to about 3.4 Torr. In various examples, the first temperature may be about 300° C. to about 400° C., and more specifically, about 325° C. to about 375° C. In various examples, the processing tools may be modified to include a gas line for argon (Ar) gas that is applied during the first deposition process for forming SiCN layer 314. In various examples, a chemical vapor deposition (CVD) process, a plasma enhanced chemical vapor deposition (PECVD) process, other suitable processing techniques, or a combination thereof made be used to form SiCN layer 314.

During the first deposition process at step 210, TMS is the silicon precursor and NH₃ is the nitrogen precursor for forming a silicon carbon nitride (SiCN) layer. While nitrogen (N₂) gas and argon (Ar) gas do not necessarily react to form SiCN layer 314, these gases may create an in situ sputter effect on the deposited SiCN layer that replaces hydrogen (H₂) and carbon (C) from the SiCN layer with nitrogen (N₂). As a result, the concentration of nitrogen may increase and the concentration of carbon may decrease in the SiCN layer 314—e.g., when compared with a C-rich SiCN layer. The increased nitrogen concentration of SiCN layer 314 may result in an improved interface between SiCN layer 314 and conductive material layer 308 (e.g., copper). The improved interface includes better adhesion between SiCN layer 314 and conductive material layer 308, better step coverage (i.e., no gaps at corner 312), less sputter from conductive material layer 308, decreased leakage due to stresses of conductive material layer 308, and overall improved reliability of device 300.

At step 212, a second treatment process is performed on SiCN layer 314. As shown in FIG. 3C, a second treatment process 316 is performed on device 300, and more specifically, on SiCN layer 314 to form an in situ treated nitrogen-rich silicon carbon nitride (IT-SiCN) layer 314′, which may also be referred to as nitrogen-rich SiCN layer (N-rich SiCN layer). The second treatment process may also be referred to as an in situ treatment process. Second treatment process 316 is performed on SiCN layer 314 in order to (i) further densify the layer, (ii) further increase nitrogen (N₂) concentration within the layer, and (iii) further reduce carbon (C) and hydrogen (H₂) content in the layer such that IT-SiCN layer 314′ can be formed. The further densification of SiCN layer 314, including increasing nitrogen (N₂) content and reducing C and H₂ content, improves the robustness of IT-SiCN layer 314′ and promotes better adhesion between IT-SiCN layer 314′ and conductive material layer 308. As illustrated in FIG. 3C, IT-SiCN layer 314′ has a first thickness t1. In various examples, first thickness t1 may be about 20 Å to about 100 Å, and more specifically, about 40 Å to about 80 Å. In other examples, first thickness t1 may be about 20 Å to about 70 Å.

In some examples, second treatment process 316 further reduces silicon hydrogen (Si—H) bonds by removing hydrogen (H₂) from the silicon and reducing silicon carbide (Si—C) bonds by removing carbon (C) from the silicon, leaving dangling silicon bonds. The nitrogen (N₂) bonds to the dangling silicon bonds increasing the concentration of nitrogen (N₂) in IT-SiCN layer 314′ and the density of IT-SiCN layer 314′. The increased nitrogen (N₂) concentration increases the robustness of IT-SiCN layer 314′.

Second treatment process 316 is performed using one or more gases at a set temperature and a set pressure for a set period of time. In various examples, the one or more gases may include nitrogen (N), ammonia (NH₃), and/or argon (Ar), or any combination thereof. In various examples, the processing tools may be modified to include a gas line for argon (Ar) gas that is applied during the second treatment process 316. Each of the one or more gases has a second flow rate. In various examples, the second flow rate of N₂ may be about 5,000 sccm to about 15,000 sccm, and more specifically, about 8,000 sccm to about 12,000 sccm. In various examples, the second flow rate of NH₃ may be about 50 sccm to about 350 sccm, and more specifically, about 75 sccm to about 150 sccm. In various examples, the second flow rate of Ar may be about 6,000 sccm to about 15,000 sccm, and more specifically, about 8,000 to about 12,000 sccm. In various examples, the second treatment process may be performed at a temperature of about 300° C. to about 400° C., and more specifically, about 325° C. to about 375° C. In various examples, the second treatment process may be performed at a pressure of about 4 Torr to about 8 Torr, and more specifically, about 5 Torr to about 7 Torr. In various examples, the second treatment process may be performed for about 10 seconds to about 60 seconds, and more specifically, about 30 seconds to about 50 seconds. In various examples, second treatment process 316 may be performed without the presence of trimethyl silane (TMS) gas. That is, in some examples second treatment process 316 may be performed without TMS gas flow.

IT-SiCN layer 314′ may be alternatively referred to as a N-rich SiCN layer, a nitrogen-rich carbon deficient layer, a carbon doped silicon nitride layer, or a treated SiCN layer. In various examples, IT-SiCN layer 314′ may be an example of first N-rich SiCN layer 122 or second N-rich SiCN layer 130 described above with reference to FIG. 1. Accordingly, IT-SiCN layer 314′ has similar properties as those described above with respect to first N-rich SiCN layer 122 and second N-rich SiCN layer 130.

For example, IT-SiCN layer 314′, in various examples, has a nitrogen concentration of greater than about 30%. In various examples, IT-SiCN layer 314′ has a nitrogen concentration of about 40% to about 50%. In various examples, IT-SiCN layer 314′ has a carbon concentration of less than about 10%. In various examples, IT-SiCN layer 314′ has a carbon concentration of about 5% to about 15%. Notably, the nitrogen concentration of IT-SiCN layer 314′ is greater than the carbon concentration. Moreover, the nitrogen concentration of IT-SiCN layer 314′ is greater than that of C-rich SiCN layer. In various examples, IT-SiCN layer 314′ has a refractive index of about 1.88 to about 1.90, and more specifically, about 1.89. In various examples, IT-SiCN layer 314′ has a dielectric constant of about 5.8 to about 6.2, and more specifically, about 5.9 to about 6.1. In various examples, IT-SiCN layer 314′ has a density of about 2.4 g/cm³ to about 2.8 g/cm³, and more specifically, about 2.6 g/cm³ to about 2.7 g/cm³. In various examples, IT-SiCN layer 314′ has a breakdown voltage of about 7 MV/cm to about 7.6 MV/cm, and more specifically, about 7.2 MV/cm to about 7.4 MV/cm. In various examples, IT-SiCN layer 314′ has an internal stress of about −200 MPa to about −600 MPa, and more specifically, about −300 MPa to about −500 MPa.

At step 214, a second deposition process is performed. As shown in FIG. 3D, a carbon-rich SiCN (C-rich SiCN) layer 318 is formed over IT-SiCN layer 314′. As illustrated in FIG. 3D, C-rich SiCN layer 318 has a second thickness t2. In various examples, second thickness t2 may be about 200 Å to about 1,000 Å, and more specifically, about 300 Å to about 800 Å. In various examples, second thickness t2 may be greater than 1,000 Å. IT-SiCN layer 314′ and C-rich SiCN layer 318 collectively form a multilayered (SiCN) film 320 similar to first multilayered SiCN film 112 or second multilayered SiCN film 118 discussed above with respect to FIG. 1.

In various examples, C-rich SiCN layer 318 may be an example of first C-rich SiCN layer 124 or second C-rich SiCN layer 132 described above in FIG. 1. Accordingly, C-rich SiCN layer 318 has similar properties as those described above with respect to first C-rich SiCN layer 124 and second C-rich SiCN layer 132. For example, C-rich SiCN layer 318, in various examples, has a nitrogen concentration of less than about 30%. In various examples, C-rich SiCN layer 318 has a nitrogen concentration of about 15% to about 30%. In various examples, C-rich SiCN layer 318 has a carbon concentration of greater than about 20%. In various examples, C-rich SiCN layer 318 has a carbon concentration of about 25% to about 35%. Notably, the carbon concentration of C-rich SiCN layer 318 may be greater than the nitrogen concentration of C-rich SiCN layer 318 in some examples. In other examples, the carbon concentration of C-rich SiCN layer 318 may be less than (or comparable to) the nitrogen concentration of C-rich SiCN layer 318. In various examples, C-rich SiCN layer 318 has a refractive index of about 1.86 to about 1.88, and more specifically, about 1.87. In various examples, C-rich SiCN layer 318 has a dielectric constant of about 5.0 to about 5.3, and more specifically, about 5.1 to about 5.2. In various examples, C-rich SiCN layer 318 has a density of about 1.9 g/cm³ to about 2.3 g/cm³, and more specifically, about 2.0 g/cm³ to about 2.2 g/cm³. In various examples, C-rich SiCN layer 318 has a breakdown voltage of about 5.3 MV/cm to about 5.9 MV/cm, and more specifically, about 5.5 MV/cm to about 5.7 MV/cm. In various examples, C-rich SiCN layer 318 has an internal stress of about −300 MPa to about −450 MPa, and more specifically, about −325 MPa to about −425 MPa.

The second deposition process at step 214, may be referred to as a fast deposition process because the deposition of C-rich SiCN layer 318 occurs at a faster rate than the first deposition process of SiCN 314 occurring at step 210. In some examples, the second deposition rate of C-rich SiCN layer 318 occurs at a deposition rate of about 25 Å/sec. In other examples, the second deposition rate of C-rich SiCN layer 318 occurs at a deposition rate of about 20 Å/sec to about 30 Å/sec. The relative faster deposition rate of the second deposition process at step 214 decreases processing time and allows for a thicker layer to be formed is less time, as compared to the first deposition process (e.g., the slow deposition process).

The second deposition process may be performed using one or more gases, at a second radio frequency (RF) power, at a second pressure, and at a second temperature. In various examples, the one or more gases may include trimethyl silane (TMS), ammonia (NH₃), and nitrogen (N₂), each gas having a third flow rate. In various examples, the third flow rate of TMS may be about 315 sccm to about 385 sccm, and more specifically, about 325 sccm to about 375 sccm. In various examples, the third flow rate of NH₃ may be about 1,450 sccm to about 1,750 sccm, and more specifically, about 1,500 sccm to about 1,700 sccm. In various examples, the third flow rate of N₂ may be about 1,100 sccm to about 1,400 sccm, and more specifically, about 1,200 sccm to about 1,300 sccm. In various examples, the first RF power may be about 600 W to about 725 W, and more specifically, about 620 W to about 680 W. In various examples, the second pressure may be about 3.1 Torr to about 3.9 Torr, and more specifically, about 3.4 Torr to about 3.6 Torr. In various examples, the second temperature may be about 300° C. to about 400° C., and more specifically, about 325° C. to about 375° C. It is noted, in some examples, unlike the first deposition process, the second deposition process is performed in the absence of applying Ar gas. In various examples, the parameters of the second deposition process may be modified based on design requirements of the integrated circuit (e.g., device 300). In various examples, a chemical vapor deposition (CVD) process, a plasma enhanced chemical vapor deposition (PECVD) process, other suitable processing techniques, or a combination thereof made be used to form C-rich SiCN layer 318.

Accordingly, in some examples, IT-SiCN layer 314′ and C-rich SiCN layer 318 have different characteristics as a result of the differing parameters used to forms these respective layers. For example, IT-SiCN layer 314′ has a higher nitrogen concentration than C-rich SiCN layer 318 and C-rich SiCN layer 318 has a higher carbon concertation than IT-SiCN layer 314′. Also, in some examples, IT-SiCN layer 314′ has a higher refractive index than C-rich SiCN layer 318. Additionally, in some examples, IT-SiCN layer 314′ has a higher dielectric constant than C-rich SiCN layer 318. Furthermore, in some examples, IT-SiCN layer 314′ is denser than C-rich SiCN layer 318. In addition, in some examples, IT-SiCN layer 314′ has a higher breakdown voltage than C-rich SiCN layer 318. In various examples, C-rich SiCN layer 318 has a lower internal stress than IT-SICN layer 314′. Thus, method 200 enables the formation of a multilayered SiCN film having different layers with different properties.

At step 216 additional processing steps are performed. For example, a processing chamber may be purged using nitrogen (N₂) to remove any residual gases and/or particles from the chamber in which device 300 was being processed. In various examples, additional materials may be formed on and over device 300, including dielectric materials, contacts, interconnects, and the like. For examples, additional process steps may occur before, during or after method 200 to form a device similar to device 100 of FIG. 1.

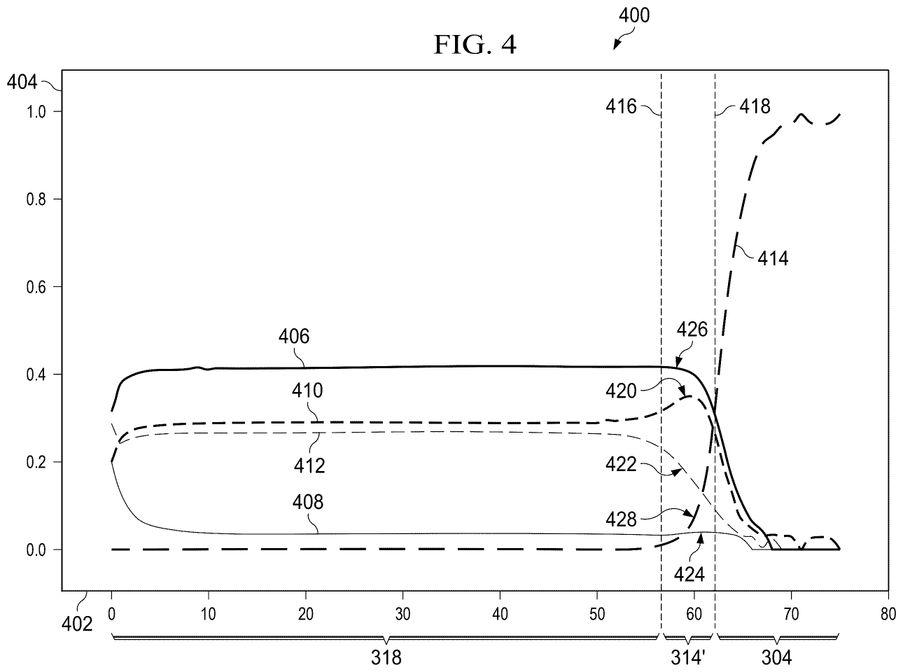

Referring now to FIG. 4, a graph 400 of an X-ray photoelectron spectroscopy (XPS) depth analysis of device 300 is illustrated. In various examples, graph 400 may be an XPS depth analysis of other semiconductor devices manufactured in accordance with the steps of method 200. Graph 400 includes a first axis 402, a second axis 404, a silicon concentration line 406, an oxygen concentration line 408, a nitrogen concentration line 410, a carbon concentration line 412, and a copper concentration line 414. First axis 402 indicates the average depth in the sample (e.g., along arrow 330 in FIG. 3D) at which the XPS analysis occurred and second axis 404 indicates the percentage of each element found at the depth indicated by first axis 402. Also, as shown along first axis 402, portions of the depth are identified as respective corresponding portions of carbon-rich silicon carbon nitride (C-rich SiCN) layer 318, in situ treated nitrogen-rich silicon carbon nitride (IT-SiCN) layer 314′, and conductive feature 304 of FIG. 3 as the analysis occurs deeper along the direction of arrow 330 in FIG. 3D. Silicon concentration line 406, oxygen concentration line 408, nitrogen concentration line 410, carbon concentration line 412, and copper concentration line 414 represent the percentage of silicon, oxygen, nitrogen, carbon, and copper, respectively in graph 400.

Graph 400 further includes a first interface 416 and a second interface 418. First interface 416 represents the approximate interface between C-rich SiCN layer 318 and IT-SiCN layer 314′. Second interface 418 represents the approximate interface between IT-SiCN layer 314′ and conductive feature 304. Segments 420-428 represent the various concentrations of nitrogen, carbon, oxygen, silicon, and copper, respectively, within IT-SiCN layer 314′ (e.g., between first interface 416 and second interface 418). As shown, for example, relative to C-rich SiCN layer 318, IT-SiCN layer 314′ has (i) a higher nitrogen concentration as indicated by first segment 420; (ii) a lower carbon concentration as indicated by second segment 422; and (iii) a substantially steady oxygen concentration near second interface 418 as indicated by third segment 424.

As described above in FIG. 3C, the nitrogen concentration of IT-SiCN layer 314′ is substantially uniform throughout the thickness of IT-SiCN layer 314′. While first segment 420 of nitrogen concentration line 410 is illustrated as changing (or varying) in amplitude along second axis 404 (e.g., a “nitrogen hump”), this is a by-product of the XPS depth analysis. That is, the XPS depth analysis may be distorted to show such a varying nitrogen concentration within IT-SiCN layer 314′ due to non-ideal situations during the XPS depth analysis - e.g., XPS analysis front being mis-aligned to the interfaces, non-uniformity present in the interfaces. In other words, XPS analysis may exhibit transient characteristics while the analysis front progresses through both interfaces 416, 418 without necessarily showing the uniformity of the nitrogen concentration throughout IT-SiCN layer 314′—e.g., due to the thickness of the IT-SiCN layer 314′ being insufficient to establish a steady-state XPS signal. Despite the limitations in XPS analysis, the average nitrogen concentration within the IT-SiCN layer 314′ measured by XPS analysis indicates that the IT-SiCN layer 314′ has a greater nitrogen concentration than the C-rich SiCN layer 318. Similarly, second segment 422 of carbon concentration line 412 shows the lower carbon concentration (e.g., average carbon concentration) throughout IT-SiCN layer 314′ without necessarily showing the uniformity of the carbon concentration throughout IT-SiCN layer 314′.

Third segment 424 of oxygen concentration line 408 illustrates a lack of increase in oxygen content at second interface 418. The lack of increase in oxygen content may be attributed at least in-part to the pre-bake process (e.g., step 204) performed on device 300 before forming IT-SiCN layer 314′. This lower oxygen concentration at second interface 418 improves the adhesion of IT-SiCN layer 314′ to conductive material layer 308, and more generally, conductive features 304. Additionally, fourth segment 426 of silicon concentration line 406 and fifth segment 428 of copper concentration line 414 indicate the change in silicon concentration and copper concentration, respectively, as the depth analysis passes through second interface 418. In other words, due to the process of the XPS depth analysis, the change in silicon concentration and the copper concentration appears to occur before second interface 418, while still within IT-SiCN layer 314′. However, that is an artifact of the XPS depth analysis that receives information about more than just the current layer being analyzed as the depth of the analysis extends deeper into the various layers being analyzed.

Accordingly, the methods and devices disclosed herein provide an improved silicon carbon nitride (SiCN) film for use in integrated circuit components that helps resolve current leakage and improve structural reliability in an integrated circuit device. For example, disclosed herein is a nitrogen-rich in situ treated silicon carbon nitride (SiCN) layer that forms a strong interface (e.g., increased adhesion) with a conductive feature such as a metal line, via, and/or contact. In some examples, the disclosed devices include a multilayered SiCN film having two layers, also referred to as a bi-layer SiCN film. The bi-layer SiCN film includes a nitrogen-rich SiCN layer and a carbon-rich SiCN layer that is formed over the nitrogen-rich SiCN layer. In some examples, the nitrogen-rich SiCN layer has a nitrogen concentration greater than about 30% and a carbon concentration less than about 10%. The bi-layer SiCN film, and more specifically the nitrogen-rich SiCN layer, improves the adhesion of the bi-layer SiCN film to the conductive feature (e.g., the copper-based material). Devices formed using the methods of forming the bi-layer SiCN film are generally more robust and have fewer stress related defects. That is, these devices avoid and/or prevent stress related defects such as via stress migration (VSM), via chain shorts (VCS), and stress induced voiding (SIV) that may otherwise be associated with a weaker interface between SiCN and a conductive feature.

The methods described herein describe forming a multilayered SiCN film over a conductive feature. Prior to forming the multilayered SiCN film, a thermal process (e.g., a pre-bake process) is performed to remove volatile materials from a workpiece that includes the conductive feature. Thereafter, a first layer of the multilayered SiCN film is formed using trimethyl silane (TMS), ammonia (NH₃), nitrogen (N₂), and argon (Ar) in a slow deposition process. The slow deposition process forms a SiCN layer that is subsequently treated. After the slow deposition, an in situ treatment process is preformed to further densify the SiCN layer and to increase nitrogen (N₂) content and reduce carbon (C) content resulting in an in situ treated nitrogen-rich silicon carbon nitride (IT-SiCN) layer (N-rich SiCN layer). The increased density of the IT-SiCN layer promotes better adhesion to the conductive feature. A second layer of the multilayered SiCN layer is then formed based on a fast deposition process using trimethyl silane (TMS), ammonia (NH₃), and nitrogen (N₂). Unlike the slow deposition process, the fast deposition process is performed in the absence of applying Ar gas. The second layer formed based on the fast deposition is a carbon-rich SiCN layer. As a result of the slow and fast deposition processes, the IT-SiCN layer is thinner, is denser, has a higher nitrogen concentration, and has a lower carbon concentration than the carbon-rich SiCN layer. Using multiple deposition processes (e.g., slow and fast depositions) and in situ treatment improves the adhesion of the multilayered SiCN film to the conductive feature without significantly increasing the processing time. This is due to the bulk of the multilayered SiCN film being formed using the faster deposition process while the thinner IT-SiCN layer, that improves the adhesion to the conductive feature, is performed using the slower deposition process and in situ treatment.

Finally, it should be understood that any of the above-described concepts can be used alone or in combination with any or all of the other above-described concepts. Although various examples have been disclosed and described, it is understood, recognized, and/or contemplated that certain modifications would come within the scope of this disclosure. Accordingly, the description is not intended to be exhaustive or to limit the principles described or illustrated herein to any precise form. Many modifications and variations are possible in light of the above teaching.

What is claimed is:

1. A device comprising:
a first conductive feature disposed over a substrate; and
a silicon carbon nitride (SiCN) layer disposed over the first conductive feature, wherein the SiCN layer has a nitrogen concentration of greater than about 30% and a carbon concentration of less than about 10%.

2. The device of claim 1, wherein the first conductive feature includes a copper material, and
wherein the SiCN layer contacts the copper material of the first conductive feature.

3. The device of claim 1, wherein the nitrogen concentration of the SiCN layer is greater than about 40% and the carbon concentration of the SiCN layer is less than about 8%.

4. The device of claim 1, wherein the first conductive feature includes a liner layer and a bulk conductive material layer that is at least partially surrounded by the liner layer, and
wherein the SiCN layer contacts the liner layer and the bulk conductive material layer.

5. The device of claim 1, further comprising:
a second conductive feature extending through the SiCN layer to the first conductive feature.

6. The device of claim 1, further comprising:
a dielectric layer disposed over the substrate,
wherein the first conductive feature is at least partially disposed within the dielectric layer, and
wherein the SiCN layer is disposed over the dielectric layer and the first conductive feature.

7. A device comprising:
a conductive feature disposed over a substrate; and
a silicon carbon nitride (SiCN) layer disposed adjacent the conductive feature, the SiCN layer including a first portion disposed adjacent the conductive feature and a second portion disposed over the first portion, the first portion having a first nitrogen concentration and a first carbon concentration and the second portion having a second nitrogen concentration and a second carbon concentration, the second nitrogen concentration being less than the first nitrogen concentration and the second carbon concentration being greater than the first carbon concentration.

8. The device of claim 7, wherein the second carbon concentration is greater than the second nitrogen concentration in the second portion of the SiCN layer.

9. The device of claim 7, wherein the first nitrogen concentration is greater than about 30% and the second nitrogen concentration is about 20% to about 30%, and
wherein the first carbon concentration is less than about 10% and the second carbon concentration is about 25% to about 35%.

10. The device of claim 7, wherein the first nitrogen concentration is greater than about 40% and the second nitrogen concentration is less than about 30%.

11. The device of claim 7, wherein the first portion of the SiCN layer contacts the conductive feature and the second portion of the SiCN layer contacts the first portion of the SiCN layer.

12. The device of claim 11, wherein the second portion of the SiCN layer contacts the conductive feature.

13. The device of claim 12, wherein the conductive feature includes a liner layer and a metal material layer, and
wherein the first portion and the second portion of the SiCN layer contact the liner layer of the conductive feature.

14. The device of claim 7, wherein the first portion of the SiCN layer has a different dielectric constant than the second portion of the SiCN layer, and
wherein the first portion of the SiCN layer has a different density than the second portion of the SiCN layer.

15. The device of claim 7, wherein the conductive feature includes a copper material, and
wherein the first portion of the SiCN layer contacts the copper material of the conductive feature.

16. A method comprising:
forming a first silicon carbon nitride (SiCN) layer over a substrate, the first SiCN layer having a first nitrogen concentration; and
performing a first treatment process on the first SiCN layer to increase nitrogen concentration within the first SiCN layer to form a treated first SiCN layer, the treated first SiCN layer having a second nitrogen concentration that is greater than the first nitrogen concentration.

17. The method of claim 16, wherein the second nitrogen concentration of the treated first SiCN layer is greater than about 30%.

18. The method of claim 16, wherein forming the first SiCN layer over the substrate includes applying nitrogen (N₂) and argon (Ar) gases.

19. The method of claim 16, wherein performing the first treatment process on the first SiCN layer to increase nitrogen concentration within the first SiCN layer to form the treated first SiCN layer includes applying ammonia (NH₃), nitrogen (N₂), and argon (Ar) gases.

20. The method of claim 16, wherein the first SiCN layer has a first density after forming the first SiCN layer over the substrate, and
wherein the treated first SiCN layer has a second density after performing the first treatment process, the second density being greater than the first density.

21. The method of claim 16, further comprising:
baking the substrate prior to forming the first SiCN layer over the substrate; and
performing a second treatment process on the substrate to remove oxide from the substrate prior to forming the first SiCN layer over the substrate.

22. The method of claim 16, wherein the substrate includes a dielectric layer having a conductive feature at least partially disposed within the dielectric layer, and
wherein forming the first SiCN layer over the substrate includes forming the first SiCN layer directly on the conductive feature and the dielectric layer.

23. The method of claim 16, further comprising:
forming a second SiCN layer over the treated first SiCN layer, the second SiCN layer having a third nitrogen concentration that is less than the second nitrogen concentration.

24. The method of claim 23, wherein forming the first SiCN layer over the substrate occurs while applying argon gas, and
wherein forming the second SiCN layer over the treated first SiCN layer occurs without applying argon gas.

25. The method of claim 23, wherein forming the first SiCN layer over the substrate occurs at a first deposition rate, and
wherein forming the second SiCN layer over the treated first SiCN layer occurs at a second deposition rate that is greater than the first deposition rate.

26. The method of claim 23, wherein forming the first SiCN layer over the substrate occurs at a first radio frequency (RF) power, and
wherein forming the second SiCN layer over the treated first SiCN layer occurs at a second RF power that is greater than the first RF power.
